(19) United States
(12) Patent Application Publication
(10) Pub. No.: US 2026/0238176 A1
(43) Pub. Date: Aug. 13, 2026

(54) BANDWIDTH BOOST TECHNIQUE FOR WIDEBAND INPUT TERMINATION NETWORK

(71) Applicant: Marvell Asia Pte Ltd, Singapore (SG)

(72) Inventors: Zushu Yan, Cupertino, CA (US); Manisha Gambhir, Cupertino, CA (US); Ahmed Mostafa, San Jose, CA (US)

(73) Assignee: Marvell Asia Pte Ltd, Singapore (SG)

(21) Appl. No.: 19/535,725

(22) Filed: Feb. 10, 2026

Related U.S. Application Data
(60) Provisional application No. 63/757,669, filed on Feb. 12, 2025.

(51) Int. Cl. H03H 7/38; H04L 25/02; H04L 25/03

(52) U.S. Cl. CPC H03H 7/38; H04L 25/0272; H04L 25/0278; H04L 25/028; H04L 25/0292; H04L 25/0298; H04L 25/03057

(57) ABSTRACT

Some input termination networks in SerDes architectures, such as inductive-capacitive (LC) transmission‑line based structures or double T‑coil networks, offer only limited ability to extend bandwidth or control peaking. To address these challenges, an improved input termination network can be implemented. The improved input termination network includes a series impedance circuit between the T-coil network and the termination circuit. By isolating the T‑coil from the full capacitive loading of the termination circuit, the series impedance circuit significantly enhances the bandwidth and tunability of the input termination network, allowing more effective shaping of peaking and return‑loss characteristics. When combined with a parallel capacitor added to the termination circuit to stabilize high‑frequency impedance, the improved input termination network enables a more controlled and robust frequency response than other passive matching networks.

### PRIORITY APPLICATION

This patent application claims priority to and/or receives benefit from U.S. Provisional Application No. 63/757,669, titled “Bandwidth Boost Technique for Wideband Input Termination Network,” filed on February 12, 2025. The U.S. Provisional Application is hereby incorporated by reference in its entirety.

### BACKGROUND

High-speed, high-bandwidth communication systems are integral to modern computing and networking applications. These systems are designed to facilitate efficient and reliable data transmission over various media or communication links, including optical fibers, copper cables, and wireless channels. Advances in communication technologies, such as improvements in analog circuit designs in an analog front-end, signal modulation, error correction, and clock recovery, can ensure data integrity, reduce latency, and maintain synchronization across devices.

### BRIEF DESCRIPTION OF THE DRAWINGS

Examples will be readily understood by the following detailed description in ‎conjunction with the accompanying drawings. To facilitate this description, like reference ‎numerals designate like structural elements. Examples are illustrated by way of ‎example, and not by way of limitation, in the figures of the accompanying drawings.

FIG. 1 illustrates a receiver architecture, according to some examples of the disclosure.

FIG. 2 illustrates an example input termination network, according to some examples of the disclosure.

FIG. 3 illustrates an example input termination network having a series impedance circuit and an improved termination circuit, according to some examples of the disclosure.

FIG. 4 illustrates example circuit implementations of the series impedance circuit, according to some examples of the disclosure.

FIG. 5 depicts a flow chart illustrating a method performed by an analog front-end of a receiver, according to some examples of the disclosure.

### DETAILED DESCRIPTION

### Overview

High‑speed Serializer‑Deserializer (SerDes) receivers operating at high data rates, e.g., beyond 112 Gbps, place increasingly stringent demands on their input termination networks. At such speeds, it is important for the input termination network to provide a wideband, low‑loss signal path to drive the large capacitive load presented by the subsequent gain stage of an analog front-end of the receiver while maintaining low noise and a well‑controlled return‑loss profile.

Some input termination networks in SerDes architectures, such as inductive-capacitive (LC) transmission‑line based structures or double T‑coil networks, offer only limited ability to extend bandwidth or control peaking, when confronted with the substantial parasitic capacitance of the termination resistor array. This parasitic capacitance lowers the high‑frequency impedance of the termination network, constraining the achievable gain‑bandwidth and reducing return‑loss performance. Furthermore, those input termination networks provide little design freedom to independently adjust peak gain and return loss, forcing designers into suboptimal trade‑offs that limit overall system performance.

To address these challenges, an improved input termination network can be implemented. The improved input termination network includes a series impedance circuit between the T-coil network and the termination circuit. By isolating the T‑coil from the full capacitive loading of the termination circuit, the series impedance circuit significantly enhances the bandwidth and tunability of the input termination network, allowing more effective shaping of peaking and return‑loss characteristics.

By introducing a series impedance, the T-coil network is effectively isolated from this capacitive loading, allowing the impedance seen by the T-coil to remain broader and more stable across frequency. The series impedance can act as an additional filter order, improving the input termination network to shape the frequency response, extract more gain at higher frequencies, and control the peaking profile. At the same time, the series impedance circuit provides meaningful noise isolation because termination resistors can be significant noise contributors at high frequencies. The additional isolation provided by the series impedance circuit limits the amount of high‑frequency noise that reaches the subsequent gain stage input, where gain is typically highest. The isolation effect is significant and contributes to improved overall signal integrity. Furthermore, the added impedance can help reconcile the mismatch between the very high, open input impedance of the gain stage input path and the termination path (e.g., typically 50‑Ω, or 100‑Ω in a fully differential implementation), improving how the two branches or paths are forked and allowing more balanced impedance matching across the full operating bandwidth.

In some examples, the input termination network includes a T-coil network coupled to an input bump of the receiver, a termination circuit, and a series impedance circuit coupled to a circuit node of the T-coil network and the termination circuit.

In some examples, the input termination network includes a T-coil network coupled to an input bump of the receiver, a termination circuit having a capacitance, and a series impedance circuit coupled to a circuit node of the T-coil network. The series impedance circuit is disposed between the T-coil network and the capacitance of the termination circuit.

In some examples, the input termination network includes a T-coil network to interface between an input bump and a stage of the analog front-end receiver, a termination circuit to provide a line termination impedance, and a series impedance circuit to isolate the T-coil network from a capacitive loading of the termination circuit.

When combined with a parallel capacitor added to the termination circuit to stabilize high‑frequency impedance, the improved input termination network enables a more controlled and robust frequency response than other passive matching networks. While the series impedance circuit increases high‑frequency impedance, the termination circuit tends to experience an undesired impedance collapse at high frequencies due to its intrinsic parasitic capacitance. The inclusion of a parallel capacitor allows the circuit to reshape the high‑frequency impedance, so that the termination continues to approximate its nominal value (e.g., 50 Ω) over a much wider frequency range. In some scenarios, the series impedance can cause the high‑frequency termination impedance to become large; the parallel capacitor in the termination circuit can pull that impedance back toward the desired region, yielding a more controlled match. The impedance of the series impedance and the parallel capacitance in the termination network can be co‑optimized, offering additional circuit design flexibility that double T‑coil networks lack.

The combined effect is a significantly enhanced bandwidth, a more predictable and tunable peaking response, better input return loss (how much signal reflects back towards the source, or S11) and forward gain or insertion gain (how effectively the input termination network passes signal through or S21) trade‑off control, and reduced noise coupling from the termination. These advantages become increasingly useful for next generation SerDes architectures, especially for 224 Gbps class receivers and beyond, where LC-based or T-coil only input termination networks cannot deliver sufficient bandwidth or matching performance. The improved input termination network provides a practical and effective solution for next‑generation SerDes technologies.

### Example receiver architecture

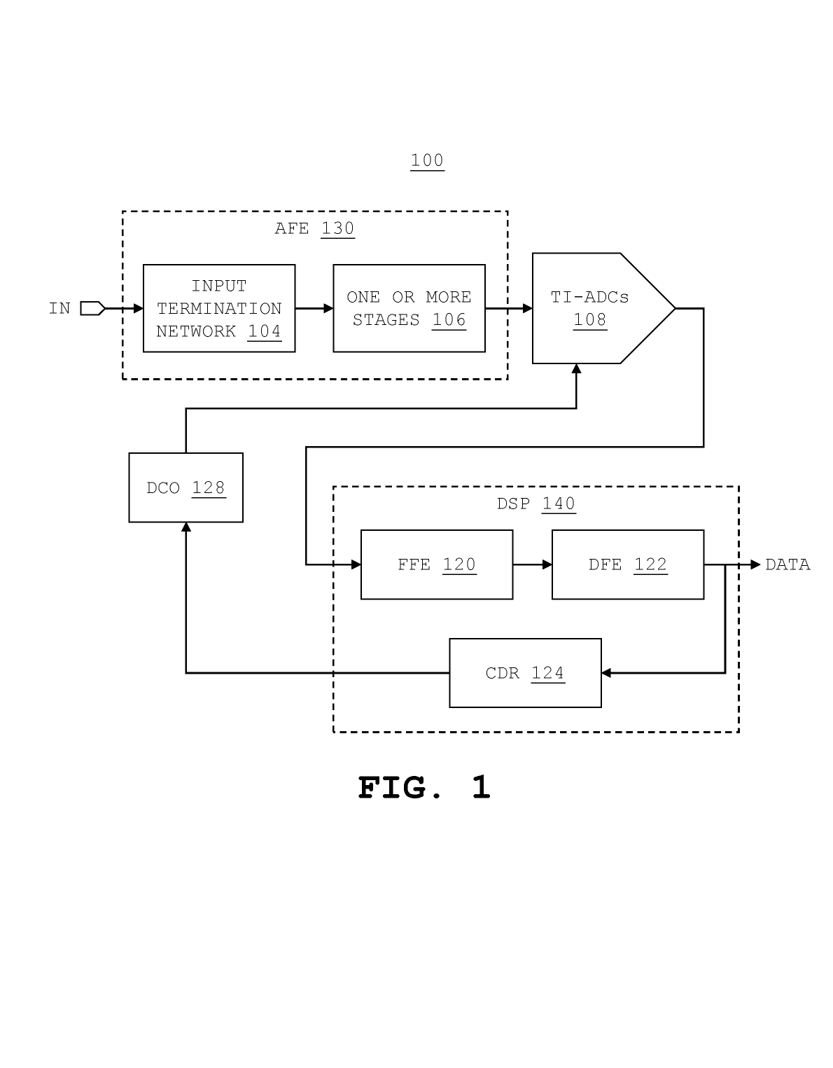

FIG. 1 illustrates receiver architecture 100, according to some examples of the disclosure. Receiver architecture 100 comprises one or more of: analog front-end (AFE) 130, time-interleaved analog-to-digital converters (TI-ADCs) 108, digital signal processor (DSP) 140, and digitally controlled oscillator (DCO) 128. Receiver architecture 100 processes an input signal shown as “IN” and outputs recovered data shown as “DATA”.

AFE 130 comprises one or more of: input termination network 104 and one or more stages 106. Input termination network 104 can include impedance matching circuitry to terminate the incoming signal IN to reduce reflections and maintain signal integrity. Input termination network 104 can include passive circuit components such as resistors, capacitors, or inductors arranged to provide impedance matching for the incoming signal. These passive circuit components help minimize reflections, maintain signal integrity, and stabilize the input interface without requiring active circuitry. One or more stages 106 can include one or more of: amplification stage(s), equalization stage(s), gain stage(s), active stage(s), and filtering stage(s) to condition the signal prior to digitization. In some examples, AFE 130 may implement gain control and bandwidth shaping in one or more stages 106 to optimize signal quality for subsequent conversion. In some examples, AFE 130 may implement CTLE in one or more stages 106 to apply frequency-dependent gain to compensate for channel loss at high frequencies. CTLE can boost attenuated high-frequency components while reducing low-frequency gain and improve signal integrity before analog-to-digital conversion. In some examples, AFE 130 may implement one or more analog signal conditioning stages, such as one or more of a variable gain amplifier stage, a transconductance stage, a transimpedance stage, a filtering stage, a gain stage, and an equalization stage. In some examples, a stage in AFE 130 may perform one or more functions, such as one or more of CTLE, transconductance conversion, transimpedance conversion, broadband gain shaping, impedance matching, conditioning operation, and signal shaping operation. In some examples, AFE 130 may include one or more discrete stages or circuits.

TI-ADCs 108 can include multiple interleaved ADCs to sample the conditioned signal at high effective rates and perform analog-to-digital conversion. TI-ADCs 108 can operate with phase alignment and calibration mechanisms to mitigate timing mismatches and improve linearity. In some examples, TI-ADCs 108 may provide digital outputs to DSP 140 for further processing. While receiver architecture 100 utilizes TI-ADCs 108, it is envisioned that other high-speed ADC architectures can be implemented to digitize the conditioned signal from AFE 130 at high data rates.

DSP 140 comprises one or more of: feed-forward equalizer (FFE) 120, decision feedback equalizer (DFE) 122, and clock and data recovery (CDR) 124. DSP 140 may receive one or more digital outputs from TI-ADCs 108 and output processed/recovered data (“DATA”) for further processing.

FFE 120 can include a set of filter taps configured to compensate for channel impairments such as inter-symbol interference (ISI) by applying a linear correction to the digitized signal. In some examples, FFE 120 may adapt its coefficients based on error feedback.

DFE 122 can include feedback taps configured to cancel post-cursor ISI by subtracting estimated interference from previously detected symbols. DFE 122 can operate in conjunction with FFE 120 to improve overall signal fidelity. In some examples, DFE 122 may employ adaptive algorithms to optimize tap weights dynamically.

CDR 124 can include phase detectors and loop filters to recover timing information from the incoming data stream. CDR 124 can generate a recovered clock signal used to align sampling and data decisions. In some examples, CDR 124 may provide one or more control signals to DCO 128 for frequency adjustment.

DCO 128 can generate a local clock signal for sampling and synchronization. The local clock signal is used to drive sampling by and operation of TI-ADCs 108. DCO 128 can receive control inputs from CDR 124 to adjust its frequency and phase. In some examples, DCO 128 may support fine-grained tuning for jitter reduction and timing accuracy.

### Examples of an input termination network

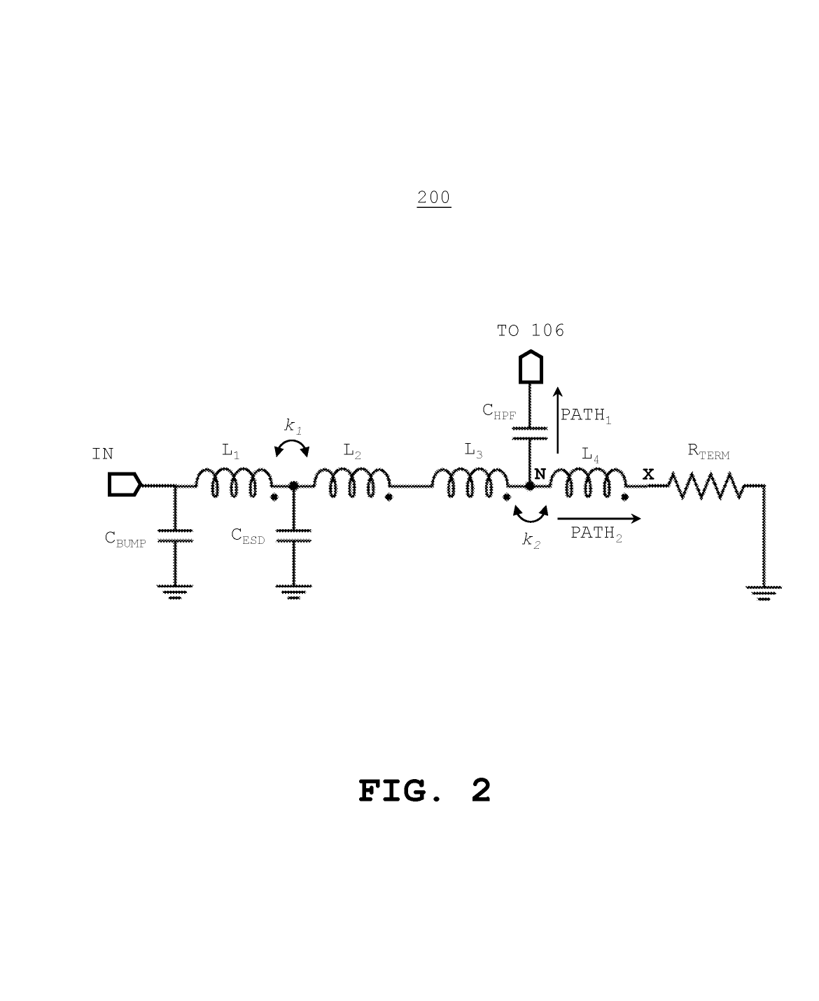

FIG. 2 illustrates an example circuit implementation 200 of input termination network 104 of FIG. 1, according to some examples of the disclosure. Circuit implementation 200 includes a T-coil network and a termination circuit.

The input bump of the receiver is labeled “IN”. The T-coil network can include one or more T-coils. In the illustration, the T-coil network includes two T-coils: a first T-coil formed by a pair of inductors (inductor L₁, inductor L₂) with a mutual coupling factor of k₁, and a second T-coil formed by a further pair of inductors (inductor L₃, inductor L₄) with a mutual coupling factor of k₂. One or more T-coils are used at high-speed input/output pads or bumps to widen bandwidth when the AFE is driving one or more substantial capacitances, e.g., parasitic capacitances from electrostatic discharge (ESD) structures and diodes (shown as C_{ESD}), pad capacitance (shown as C_{BUMP}), gain stage input device capacitance (shown as C_{HPF}), etc.

The T-coil sits between the pad and one or more stages 106 (e.g., an active amplifier). The T-coil can provide broadband impedance matching and may perform an impedance transformation that allows the driver (or the line) to see a relatively constant impedance across a much wider frequency range than a simple resistive-inductive-capacitive (RLC) network. The series-shunt inductor combination in a T-coil can reshape the impedance of the capacitive load into something closer to a real (resistive) impedance over frequency. The mutual inductance of pairs of inductors boosts effective inductance without requiring a large physical inductor. As a result, the input sees lower reflection (or better S11) and higher forward gain (S21) over a broader bandwidth. Moreover, the T-coil can provide compensation for capacitive loading, such as large shunt capacitances (e.g., C_{ESD}, C_{BUMP}, and C_{HPF}). A T-coil effectively implements multi-pole, multi-zero shaping that cancels more of the load’s reactance across a wide range. The T-coil, when duplicated in a fully differential implementation (one T-coil network per side, each T-coil network feeding a corresponding gain stage), can balance treatment of the differential paths in the AFE and reduce differential-to-common-mode conversion.

The T-coil network has a circuit node or an intermediate circuit node (shown as node N), which forks into two circuit paths (shown as path₁ and path₂). Path₁ goes towards one or more stages 106. Path₂ goes towards the termination circuit.

At high‑speed SerDes inputs, the termination circuit, represented as R_{TERM}, can include a resistor array or a resistor ladder. The termination circuit is coupled to the T-coil network at node X. The termination circuit provides the line termination, 50 Ω, to ground at each side (or a 100‑Ω differential termination). The termination circuit can have parasitic capacitance from metal routing, switches, and device junctions. The termination circuit can provide correct line termination and absorbs incoming energy to prevent reflections from the chip boundary. Therefore, the termination circuit ensures good return loss (S11). In addition, the termination circuit defines the input impedance across the entire channel bandwidth. In practice, at higher frequencies, the parasitic capacitance of the termination circuit can shunt the resistor array or ladder, and the termination impedance collapses (becomes lower than 50 Ω). This effect at higher frequencies can degrade bandwidth and increase reflections. The parasitic capacitance of the termination network reduces the effective bandwidth of the T‑coil network because the T‑coil expects to drive a certain impedance profile. The parasitic capacitance shifts the input termination network’s poles/zeros, and the high‑frequency impedance seen by the T‑coil network becomes too small. The negative effects can reduce peaking, limit gain bandwidth. Moreover, the termination circuit is a noise source, because the termination circuit adds direct, frequency-dependent noise coupling into the path going to one or more stages 106. At high frequencies, the parasitic path mediates noise directly into the signal input and couples back into the gain stage input (e.g., towards one or more stages 106). The parasitic capacitance loading is fixed and sits directly at node X, which can limit flexibility to be able to balance peaking vs. return‑loss tradeoffs.

The T-coil network is the broadband matching engine that compensates for the input bump and input capacitances and aims to deliver a wide, flat (or intentionally peaked) response into one or more stages 106. The termination circuit provides line termination, but its parasitic capacitance undermines the T-coil by reducing high-frequency impedance, limiting bandwidth, reducing peaking control, and introducing high-frequency noise coupling. Their interaction presents a core bandwidth-limiting issue for high-speed SerDes designs.

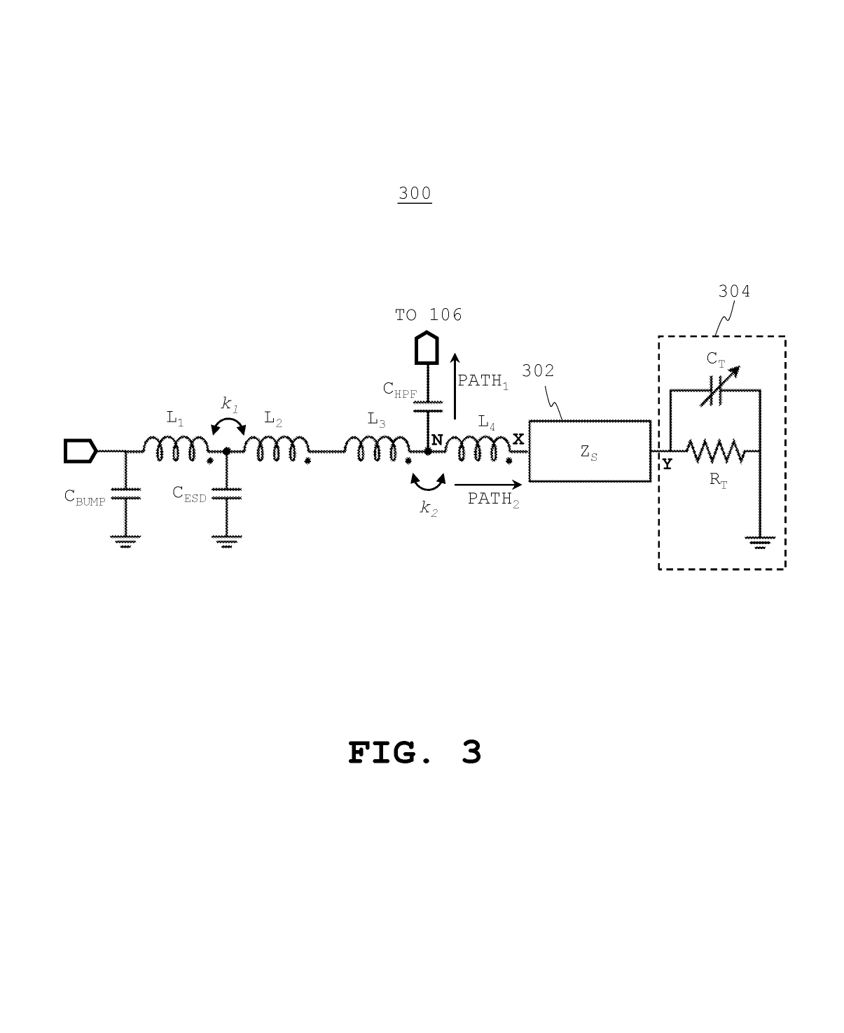

FIG. 3 illustrates an example circuit implementation 300 of input termination network 104 of FIG. 1 having series impedance circuit 302 (shown as Z_{S}) and improved termination circuit 304, according to some examples of the disclosure.

In some examples, circuit implementation 300 includes a T-coil network coupled to an input bump of the receiver (shown as “IN”), as previously described in FIG. 2. Circuit implementation 300 includes a termination circuit (e.g., R_{TERM} of FIG. 2, or improved termination circuit 304). Circuit implementation 300 further includes series impedance circuit 302 coupled to a circuit node of the T-coil network (e.g., node X) and the termination circuit (e.g., R_{TERM} of FIG. 2, or improved termination circuit 304). Series impedance circuit 302 is coupled to node X of the T-coil network and node Y of improved termination circuit 304. Series impedance circuit 302 sits between the T-coil network and improved termination circuit 304. In some examples, the T-coil network is further coupled to a CTLE circuit of the AFE (e.g., a stage in one or more stages 106).

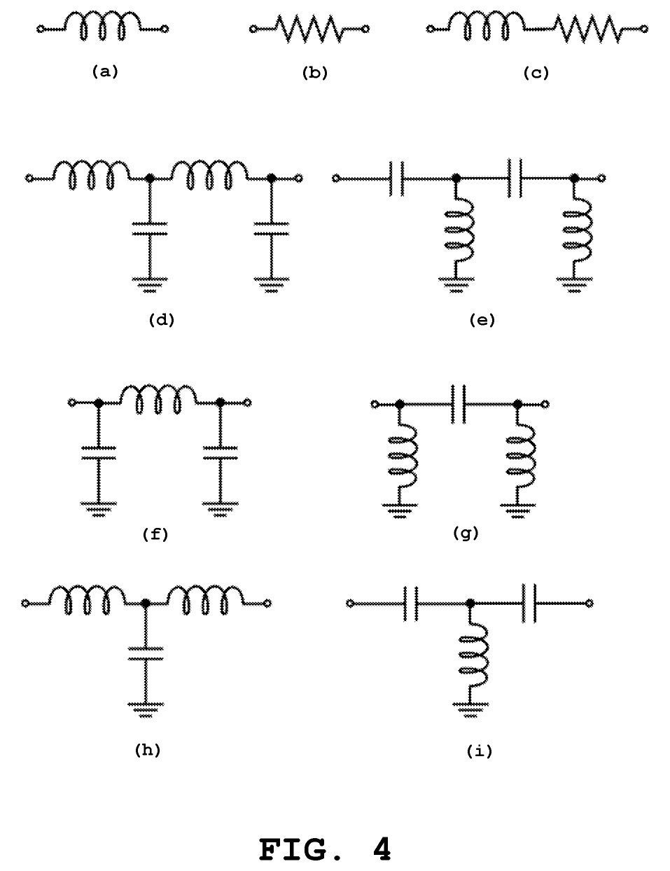

Because the T‑coil in FIG. 2 saw the full parasitic capacitance of the termination circuit, its high‑frequency bandwidth and matching were degraded. Adding series impedance circuit 302 (whose impedance is represented by Z_{S}) can achieve one or more advantages and effects. Series impedance circuit 302 can isolate the T‑coil network from a parasitic capacitance of the termination circuit, by attenuating the loading effect of the parasitic capacitance. The T-coil network in FIG. 3 interacts with a partially isolated resistive load rather than a strongly frequency‑dependent resistive load. Series impedance circuit 302 can provide an additional filter pole/zero pair. Even a single inductor in series impedance circuit 302 improves high‑frequency impedance shaping, peaking behavior, and the available gain‑bandwidth product. More degrees of freedom to shape the response of the input matching network can be obtained through using more complex circuits in series impedance circuit 302, such as LC ladders and higher-order filters, and/or including tunable circuit components or parts in series impedance circuit 302. Examples of circuit implementations of series impedance circuit 302 are illustrated in FIG. 4. Series impedance circuit 302 can improve return‑loss vs. gain tradeoffs. By adjusting Z_{S}, the circuit can increase peaking without significantly degrading S11, tune the location and magnitude of the first peaking hump, and better match the open impedance of path₁ and the impedance of path₂. More importantly, series impedance circuit 302 provides frequency noise isolation and reduces high‑frequency noise contribution from the termination circuit into the gain stage input towards one or more stages 106. One or more stages 106, e.g., a CTLE stage, tends to have high gain at high frequencies, which can amplify any noise present at high frequencies.

In some examples, improved termination circuit 304 includes a resistance (e.g., shown as R_{T}) and a capacitance in parallel to the resistance (shown as C_{T}). In some examples, the capacitance is tunable. In some examples, the resistance includes a resistor array and/or a resistor ladder.

Adding a parallel capacitor C_{T} across (or within) the termination resistance (e.g., a termination resistor array or ladder) can ensure that the termination impedance stays closer to the target resistance (e.g., 50 Ω) at high frequencies. In some scenarios, the termination resistor array or ladder can become too capacitive at high frequencies. The added intentional capacitor is counter‑intuitively used to shape the impedance so that the overall high‑frequency impedance does not roll off as severely. Improved termination circuit 304 with the added capacitance C_{T} helps because the capacitance can be used to directly control or tune the high‑frequency impedance profile. Instead of a termination circuit (e.g., as seen in FIG. 2) whose impedance collapses to a small value as frequency increases, adding the capacitance C_{T} linearizes the high‑frequency impedance, brings the magnitude back toward the desired amount of resistance, and keeps S11 under control. In addition, adding the capacitance C_{T} enables co‑optimization between C_{T} and Z_{S}. In some scenarios, Z_{S} in series impedance circuit 302 can push the high‑frequency impedance too high if not balanced. Adding the capacitance C_{T} “pulls” the high‑frequency impedance downward, allows finer shaping of the impedance profile, and lets the circuit target specific peaking frequencies and magnitudes. Moreover, adding the capacitance C_{T} adds design freedom that input termination networks (e.g., as seen in FIG. 2) lack. Without C_{T}, the termination circuit has fixed parasitic capacitance that is unaddressed, has little or no ability to shape termination impedance, and has a strong interdependence between T‑coil peaking and return‑loss behavior. The addition of a deliberate capacitor makes improved termination circuit 304 into a designable broadband element rather than a passive liability.

In some examples, circuit implementation 300 includes a T-coil network coupled to an input bump of the receiver (shown as “IN”), as previously described in FIG. 2. Circuit implementation 300 includes a termination circuit (e.g., R_{TERM} of FIG. 2, or improved termination circuit 304) having a capacitance. Circuit implementation 300 includes series impedance circuit 302 coupled to a circuit node of the T-coil network (e.g., node X). Series impedance circuit 302 is disposed between the T-coil network and the capacitance of the termination circuit. In some examples, the capacitance of the termination circuit is a parasitic capacitance. In some examples, the capacitance is a tunable capacitor (e.g., shown as C_{T}) that is parallel to a termination resistance (e.g., shown as R_{T}) of termination circuit 304. The T-coil network further includes a further circuit node (e.g., node N) that couples the T-coil network to a CTLE circuit of the AFE.

In some examples, circuit implementation 300 includes a T-coil network (e.g., as previously described in FIG. 2) to interface between an input bump (shown as “IN”) and a stage of the analog front-end receiver (e.g., a stage in one or more stages 106). Circuit implementation 300 includes a termination circuit (e.g., R_{TERM} of FIG. 2, or improved termination circuit 304) to provide a line termination impedance. Circuit implementation 300 includes series impedance circuit 302 to isolate the T-coil network from a capacitive loading of the termination circuit (e.g., R_{TERM} of FIG. 2, or improved termination circuit 304). In some examples, the termination circuit (e.g., R_{TERM} of FIG. 2, or improved termination circuit 304) includes one or more of: a parasitic capacitance and a capacitance (e.g., C_{T}) that is parallel to a termination resistance (e.g., R_{T}) of improved termination circuit 304. In some examples, the capacitance (e.g., C_{T}) that is parallel to the termination resistance (e.g., R_{T}) of termination circuit 304 is tunable.

Together, Z_{S} of series impedance circuit 302 and C_{T} of improved termination circuit 304 can provide a new, tunable broadband impedance matching subsystem in the input termination network that solves the limitations of the T-coil architecture as illustrated in FIG. 2. Bandwidth increases because the T-coil is relieved from directly driving the capacitive load of the termination network. Peaking becomes engineerable rather than accidental. Return loss improves because high-frequency impedance is controlled rather than collapsing. Noise isolation improves because Z_{S} provides a high-frequency barrier between the termination resistor noise and the signal input towards one or more stages 106. Matching at disparate impedance paths, e.g., path₁ versus path₂, becomes practical and possible. Z_{S} of series impedance circuit 302 and C_{T} of improved termination circuit 304 can provide a tunable wideband input network with superior S21/S11 tradeoffs and improved noise behavior.

In some examples, the parallel capacitance C_{T} is adjustable, tunable, programmable, or adaptable. For example, the parallel capacitance C_{T} can include one or more of: a switchable capacitor bank, a voltage-controlled capacitor or metal-oxide-semiconductor varactor, a switched varactor array, a capacitor digital-to-analog converter, etc.

FIG. 4 illustrates example circuit implementations of series impedance circuit 302 of FIG. 3, according to some examples of the disclosure. In some examples, series impedance circuit 302 includes one or more of: an inductor, a capacitor, and a resistor. In some examples, series impedance circuit 302 includes one or more of: an LC network, a resistive-capacitive (RC) network, a resistive-inductive (RL) network, and a RLC network. In some examples, series impedance circuit 302 can include switchable or tunable circuit components (e.g., a tunable resistor, a tunable inductor, and a tunable capacitor) for equalization and/or tuning. In some examples, series impedance circuit 302 can include an inductor, an inductive-capacitive network, a resistor, a resistive-capacitive network, a capacitor, an inductive-resistive network, a series network (involving one or more of a resistor, a capacitor, and an inductor), a T‑network (involving one or more of a resistor, a capacitor, and an inductor), and a π network (involving one or more of a resistor, a capacitor, and an inductor). Same types or different networks can be cascaded for higher-order effects.

Part (a) shows a series inductor. The inductor can provide inductive isolation to mitigate the loading effect of the termination capacitance and to introduce controlled high‑frequency peaking. This improves the forward gain and extends bandwidth by preventing the termination’s parasitic capacitance from collapsing the high‑frequency impedance. The inductor can also enhance peaking in a controlled manner, thereby improving the S21 response while maintaining acceptable return loss.

Part (b) shows a series resistor. The resistor provides damping to moderate resonance and to improve stability where excessive peaking would otherwise occur.

Part (c) shows a series inductor followed by a series resistor. The inductor supplies high‑frequency isolation and bandwidth extension, while the resistor controls Q‑factor and reduces overshoot for a more monotonic response. The circuit can include a series resistor followed by a series inductor instead. Combining an inductor with a resistor allows simultaneous control over both high-frequency isolation and Q-factor. The inductor enhances bandwidth and peaking, while the resistor suppresses overshoot and improves return-loss stability. In this way, the circuit can achieve a finely balanced S11/S21 tradeoff, offering wider design freedom than either element alone.

Part (d) shows an LC ladder network in which series inductors are separated by shunt capacitors to ground. Part (e) shows an LC ladder network employing series capacitors with shunt inductors to ground. One or more LC ladder networks can be cascaded for higher-order effects. LC ladder networks provide multi-order impedance shaping that allows the circuit to have multiple poles and zeros at desired locations to precisely tune the gain bandwidth, peaking, and return-loss behavior. These networks can accommodate more aggressive peaking while maintaining match quality. Cascading additional LC ladder sections further enhances the ability to isolate termination-array capacitance and create broad, stable high-frequency impedance profiles.

Part (f) shows a π‑network comprising a series inductor with shunt capacitors at the input and output nodes. Part (g) shows a π‑network with a series capacitor with shunt inductors at the input and output nodes. One or more π‑networks can be cascaded. π‑networks introduce symmetric shunt elements that offer enhanced control over both mid‑band peaking and high‑frequency roll‑off. These structures provide smoother impedance transitions between the T-coil network and the termination circuit, improving return‑loss and reducing sensitivity to layout parasitics. Because π‑networks can be cascaded, the series impedance circuit can achieve even greater shaping of S11 and S21 across wide bandwidths.

Part (h) shows a T‑network comprising series inductors with a shunt capacitor to ground between the inductors. This T‑network provides enhanced high‑frequency isolation by introducing an intermediate node where the shunt capacitor absorbs part of the termination‑induced capacitive loading. The two inductors allow more precise shaping of the impedance slope across frequency, enabling finer control of peaking magnitude, bandwidth extension, and return‑loss behavior. The central shunt capacitor also helps stabilize sensitivity to process‑dependent parasitics, resulting in a more predictable impedance profile than a single‑inductor implementation. One or more T‑networks can be cascaded.

Part (i) shows a T‑network comprising series capacitors with a shunt inductor to ground between the capacitors. This configuration provides a complementary impedance‑shaping effect. The series capacitors limit low‑frequency loading while the shunt inductor restores inductive behavior near and above the peaking region. The topology allows the circuit to tailor the high‑frequency impedance upward without over‑boosting mid‑band gain, thereby improving S11 matching while maintaining adequate S21 gain. The structure is especially advantageous in compensating the termination‑array capacitance, allowing for more flexibility to flatten or accentuate peaking across a wide operating bandwidth. One or more T‑networks can be cascaded.

### Examples of methods performed by an input termination network in analog front-end circuitry

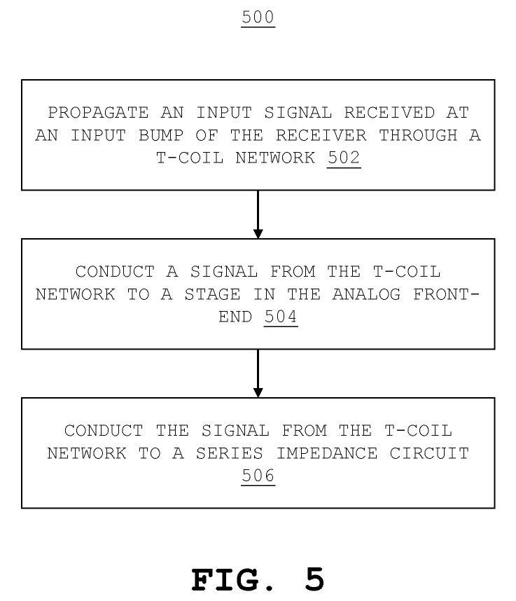

FIG. 5 depicts a flow chart illustrating method 500 performed by an analog front-end of a receiver, according to some examples of the disclosure.

In 502, an input signal received at an input bump of the receiver is propagated through a T-coil network.

In 504, a signal from the T-coil network is conducted to a stage in the analog front-end, e.g., via a first circuit path.

In 506, the signal from the T-coil network is conducted to a series impedance circuit, e.g., via a second circuit path. The series impedance circuit is disposed between the T-coil network and a termination circuit.

In some examples, method 500 further includes tuning a capacitance of the termination circuit.

In some examples, the series impedance network comprises one or more of: the series impedance comprises at least one of: an inductor, an inductive-capacitive network, a resistor, a resistive-capacitive network, a capacitor, an inductive-resistive network, a series network, a T‑network, and a π-network.

### Select examples

Example 1 provides an input termination network for an analog front-end of a receiver, where the input termination network includes a T-coil network coupled to an input bump of the receiver; a termination circuit; and a series impedance circuit coupled to a circuit node of the T-coil network and the termination circuit.

Example 2 provides the input termination network of example 1, where the series impedance circuit includes one or more of: an inductor, a capacitor, and a resistor.

Example 3 provides the input termination network of example 1 or 2, where the series impedance circuit includes an inductive-capacitive network.

Example 4 provides the input termination network of any one of examples 1-3, where the series impedance circuit includes a resistive-inductive network.

Example 5 provides the input termination network of any one of examples 1-4, where the termination circuit includes a resistance and a capacitance in parallel.

Example 6 provides the input termination network of example 5, where the capacitance is tunable.

Example 7 provides the input termination network of any one of examples 1-6, where the T-coil network is further coupled to a continuous-time linear equalizer circuit of the analog front-end.

Example 8 provides an input termination network for an analog front-end of a receiver, where the input termination network includes a T-coil network coupled to an input bump of the receiver, where the T-coil network has a circuit node; a termination circuit having a capacitance; and a series impedance circuit coupled to the circuit node of the T-coil network, where the series impedance circuit is disposed between the T-coil network and the capacitance of the termination circuit.

Example 9 provides the input termination network of example 8, where the series impedance circuit includes one or more of: an inductor, a capacitor, and a resistor.

Example 10 provides the input termination network of example 8 or 9, where the series impedance circuit includes an inductive-capacitive network.

Example 11 provides the input termination network of any one of examples 8-10, where the series impedance circuit includes a resistive-inductive network.

Example 12 provides the input termination network of any one of examples 8-11, where the capacitance of the termination circuit is a parasitic capacitance.

Example 13 provides the input termination network of any one of examples 8-11, where the capacitance is a tunable capacitor that is parallel to a termination resistance of the termination circuit.

Example 14 provides the input termination network of any one of examples 8-13, where the T-coil network further includes a further circuit node that couples the T-coil network to a continuous-time linear equalizer circuit of the analog front-end.

Example 15 provides an input termination network for an analog front-end of a receiver, where the input termination network includes a T-coil network to interface between an input bump and a stage of the analog front-end; a termination circuit to provide a line termination impedance; and a series impedance circuit to isolate the T-coil network from a capacitive loading of the termination circuit.

Example 16 provides the input termination network of example 15, where the series impedance circuit includes one or more of: an inductor, a capacitor, and a resistor.

Example 17 provides the input termination network of example 15 or 16, where the series impedance circuit includes an inductive-capacitive network.

Example 18 provides the input termination network of any one of examples 15-17, where the series impedance circuit includes a resistive-inductive network.

Example 19 provides the input termination network of any one of examples 15-18, where the termination circuit includes one or more of: a parasitic capacitance and a capacitance that is parallel to a termination resistance of the termination circuit.

Example 20 provides the input termination network of example 19, where the capacitance that is parallel to the termination resistance of the termination circuit is tunable.

Example 21 provides an input termination network for an analog front-end of a receiver, where the input termination network includes a T-coil network circuit means for interfacing between an input bump and a stage of the analog front-end; a termination circuit means for providing a line termination impedance; and a series impedance circuit means for isolating the T-coil network circuit means from a capacitive loading of the termination circuit means.

Example 22 provides the input termination network of example 21, where the termination circuit means includes one or more of: a parasitic capacitance circuit means and a capacitance circuit means that is parallel to a termination resistance circuit means of the termination circuit means.

Example 23 provides the input termination network of example 22, where the capacitance circuit means that is parallel to the termination resistance circuit means of the termination circuit means is tunable.

Example 24 provides a method performed by an analog front-end of a receiver, where the method includes propagating an input signal received at an input bump of the receiver through a T-coil network; conducting a signal from the T-coil network to a stage in the analog front-end; and conducting the signal from the T-coil network to a series impedance circuit, where the series impedance circuit is disposed between the T-coil network and a termination circuit.

Example 25 provides the method of example 24, further including tuning a capacitance of the termination circuit.

Example 26 provides the method of example 24 or 25, where the series impedance circuit includes one or more of: an inductor, an inductive-capacitive network, a resistor, a resistive-capacitive network, a capacitor, an inductive-resistive network, a series network, a T-network, and a network.

Example 27 provides an apparatus comprising means for performing a method according to any one of examples 24-26.

### Variations, details, and/or remarks

The detailed description, such as the "Select examples" section, provides various examples of the examples disclosed herein.

As used herein, the term "coupled to" or "coupled with" refers to a relationship between electronic components or circuit elements wherein the components are in electronic communication with one another and are capable of transmitting and/or receiving electrical signals between them. The term "coupled to" does not require a direct physical or electrical connection between the coupled components. Rather, "coupled to" can encompass arrangements where the components are connected through one or more intervening elements, components, circuits, or transmission paths. For example, a first component may be "coupled to" a second component through intermediate components such as resistors, capacitors, inductors, transistors, logic gates, buses, transformers, or other electronic components, or through intermediate transmission paths, while still maintaining the capability for electronic communication between the first and second components.

The description of illustrated implementations herein, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations.

Further, references are made to the accompanying drawings that form a part hereof, and in which are shown, by way of illustration, examples that may be practiced. It is to be understood that other examples may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described example. Various additional operations may be performed or described operations may be omitted in additional examples.

For the purposes of the present disclosure, the phrase “A or B” or the phrase "A and/or B" means (A), (B), or (A and B). For the purposes of the present disclosure, the phrase “A, B, or C” or the phrase "A, B, and/or C" means (A), (B), (C), (A and B), (A and C), (B and C), or (A, B, and C). The term "between," when used with reference to measurement ranges, is inclusive of the ends of the measurement ranges. For the purposes of the present disclosure, the phrase “one or more of A, B, and C”, the phrase "at least one of A, B, and C", or the phrase "at least one or more of A, B, and C" means (A), (B), (C), (A and B), (A and C), (B and C), or (A, B, and C). The term "between," when used with reference to measurement ranges, is inclusive of the ends of the measurement ranges.

The description uses the phrases "in an example" or "in examples," which may each refer to one or more of the same or different examples. The terms "comprising," "including," "having," and the like, as used with respect to examples of the present disclosure, are synonymous. The disclosure may use perspective-based descriptions such as "above," "below," "top," "bottom," and "side" to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking, or in any other manner.

The terms “substantially,” “close,” “approximately,” “near,” and “about,” generally refer to being within +/- 20% of a target value as described herein or as known in the art. Similarly, terms indicating orientation of various elements, e.g., “coplanar,” “perpendicular,” “orthogonal,” “parallel,” or any other angle between the elements, generally refer to being within +/- 5-20% of a target value as described herein or as known in the art.

In addition, the terms “comprise,” “comprising,” “include,” “including,” “have,” “having,” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods, and devices of this disclosure each have several innovative aspects, no single one of which is solely responsible for all desirable attributes disclosed herein. Details of one or more implementations of the subject matter described in this specification are set forth in the description and the accompanying drawings.

1. An input termination network for an analog front-end of a receiver, wherein the input termination network comprises:
a T-coil network coupled to an input bump of the receiver;
a termination circuit; and
a series impedance circuit coupled to a circuit node of the T-coil network and the termination circuit.

2. The input termination network of claim 1, wherein the series impedance circuit comprises one or more of: an inductor, a capacitor, and a resistor.

3. The input termination network of claim 1, wherein the series impedance circuit comprises an inductive-capacitive network.

4. The input termination network of claim 1, wherein the series impedance circuit comprises a resistive-inductive network.

5. The input termination network of claim 1, wherein the termination circuit includes a resistance and a capacitance in parallel.

6. The input termination network of claim 5, wherein the capacitance is tunable.

7. The input termination network of claim 1, wherein the T-coil network is further coupled to a continuous-time linear equalizer circuit of the analog front-end.

8. An input termination network for an analog front-end of a receiver, wherein the input termination network comprises:
a T-coil network coupled to an input bump of the receiver, wherein the T-coil network has a circuit node;
a termination circuit having a capacitance; and
a series impedance circuit coupled to the circuit node of the T-coil network, wherein the series impedance circuit is disposed between the T-coil network and the capacitance of the termination circuit.

9. The input termination network of claim 8, wherein the series impedance circuit comprises one or more of: an inductor, a capacitor, and a resistor.

10. The input termination network of claim 8, wherein the series impedance circuit comprises an inductive-capacitive network.

11. The input termination network of claim 8, wherein the series impedance circuit comprises a resistive-inductive network.

12. The input termination network of claim 8, wherein the capacitance of the termination circuit is a parasitic capacitance.

13. The input termination network of claim 8, wherein the capacitance is a tunable capacitor that is parallel to a termination resistance of the termination circuit.

14. The input termination network of claim 8, wherein the T-coil network further includes a further circuit node that couples the T-coil network to a continuous-time linear equalizer circuit of the analog front-end.

15. An input termination network for an analog front-end of a receiver, wherein the input termination network comprises:
a T-coil network to interface between an input bump and a stage of the analog front-end;
a termination circuit to provide a line termination impedance; and
a series impedance circuit to isolate the T-coil network from a capacitive loading of the termination circuit.

16. The input termination network of claim 15, wherein the series impedance circuit comprises one or more of: an inductor, a capacitor, and a resistor.

17. The input termination network of claim 15, wherein the series impedance circuit comprises an inductive-capacitive network.

18. The input termination network of claim 15, wherein the series impedance circuit comprises a resistive-inductive network.

19. The input termination network of claim 15, wherein the termination circuit includes one or more of: a parasitic capacitance and a capacitance that is parallel to a termination resistance of the termination circuit.

20. The input termination network of claim 19, wherein the capacitance that is parallel to the termination resistance of the termination circuit is tunable.

21. An input termination network for an analog front-end of a receiver, wherein the input termination network comprises:
a T-coil network circuit means for interfacing between an input bump and a stage of the analog front-end;
a termination circuit means for providing a line termination impedance; and
a series impedance circuit means for isolating the T-coil network circuit means from a capacitive loading of the termination circuit means.

22. The input termination network of claim 21, wherein the termination circuit means includes one or more of: a parasitic capacitance circuit means and a capacitance circuit means that is parallel to a termination resistance circuit means of the termination circuit means.

23. The input termination network of claim 22, wherein the capacitance circuit means that is parallel to the termination resistance circuit means of the termination circuit means is tunable.
